(19) United States
(12) Patent Application Publication
(10) Pub. No.: US 2022/0238737 A1
(43) Pub. Date: Jul. 28, 2022

(54) FABRICATING A SEMICONDUCTOR STRUCTURE WITH MULTIPLE QUANTUM WELLS

(71) Applicant: SMART Photonics Holding B.V., Eindhoven (NL)

(72) Inventors: Steven Everard Filippus KLEIJN, Eindhoven (NL); Petrus Johannes Adrianus THIJS, Eindhoven (NL)

(21) Appl. No.: 17/720,851

(22) Filed: Apr. 14, 2022

Related U.S. Application Data
(63) Continuation of application No. PCT/EP2020/079294, filed on Oct. 16, 2020.

(30) Foreign Application Priority Data
Oct. 23, 2019 (GB) 1915377.4

(51) Int. Cl. H01L 31/0352; H01L 31/0304; H01L 31/18; H01S 5/343

(52) U.S. Cl. CPC H01L 31/035236; H01S 5/3434; H01L 31/1844; H01L 31/03046

(57) ABSTRACT

A method of fabricating a semiconductor structure with multiple quantum wells, comprising: providing a substrate comprising a binary semiconductor compound having a first lattice constant; depositing: a first layer on the substrate, the first layer of a first semiconductor alloy, and a second layer in contact with the first layer, the second layer of a second semiconductor alloy, to form a first stack of substantially planar semiconductor layers on the substrate; depositing in contact with the first stack a third layer of a binary semiconductor compound having the first lattice constant; depositing at least: a fourth layer on the third layer, the fourth layer comprising a third semiconductor alloy comprising InP, and a fifth layer in contact with the fourth layer, the fifth layer comprising a fourth semiconductor alloy comprising InP, to form a second stack of substantially planar semiconductor layers on the third layer.

### CROSS-REFERENCE TO RELATED APPLICATIONS

This application is a continuation of International Application No. PCT/EP2020/079294, filed Oct. 16, 2020, which claims priority to United Kingdom Application No. GB 1915377.4, filed Oct. 23, 2019, under 35 U.S.C. § 119(a). Each of the above referenced patent applications is incorporated by reference in its entirety.

### BACKGROUND

### Field of the Invention

Quantum wells are commonly used in semiconductor structures to provide electronic confinement. For example, in optoelectronics devices, quantum wells are used to tune the electronic band gap, thereby tuning the energy (or frequency) of photons that are emitted (in the case of emitters) or absorbed (in the case of absorbers).

In many applications the effect of a quantum well can be increased by providing multiple quantum wells in a stack. In the case of an emitter, such as a laser, this may increase the rate of stimulated emission in the emitter, whereas in the case of an absorber, it may increase the rate of absorption.

A commonly commercially utilised material platform for optoelectronic devices is indium phosphide (InP), which allows for integration of optically active and passive functions into so-called photonic integrated circuits (PICs).

It is desirable to provide a more reliable method of fabricating a semiconductor structure with multiple quantum wells.

### BRIEF DESCRIPTION OF THE DRAWINGS

FIG. 1 is a flow diagram illustrating a method of fabricating a semiconductor structure with multiple quantum wells, according to examples;

FIG. 2 is a scanning electron micrograph of a semiconductor structure with multiple InP-containing quantum wells, showing defects in the resulting structure;

FIG. 3 is a scanning electron micrograph of a semiconductor structure with multiple quantum wells not containing InP;

FIG. 4 is a schematic diagram of a semiconductor structure, according to examples; and

FIG. 5 is a scanning electron micrograph of a semiconductor structure with multiple InP-containing quantum wells, according to examples.

### DETAILED DESCRIPTION

Examples described herein relate to methods of fabricating semiconductor structures. In particular, but not exclusively, they relate to fabricating semiconductor structures with multiple quantum wells.

As will be elaborated below, at least in the example of a semiconductor structure with quantum wells comprising InP, examples described herein provides an improved semiconductor structure. Accordingly, such a structure may provide reduced scattering of light being transmitted through the structure, may provide increased rates of stimulated emission in light emitting portions and may provide increased rates of absorption in light absorbing portions. This allows for a more efficient optoelectronic devices and therefore for a more efficient PIC.

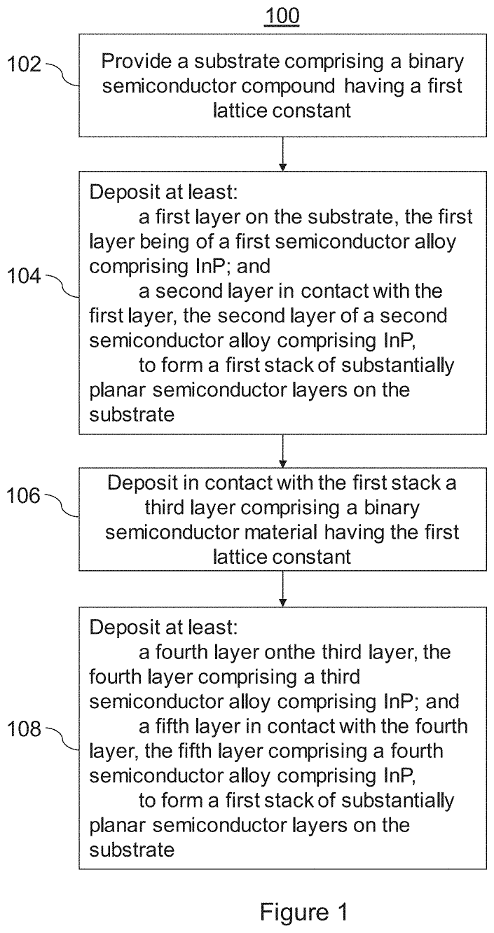

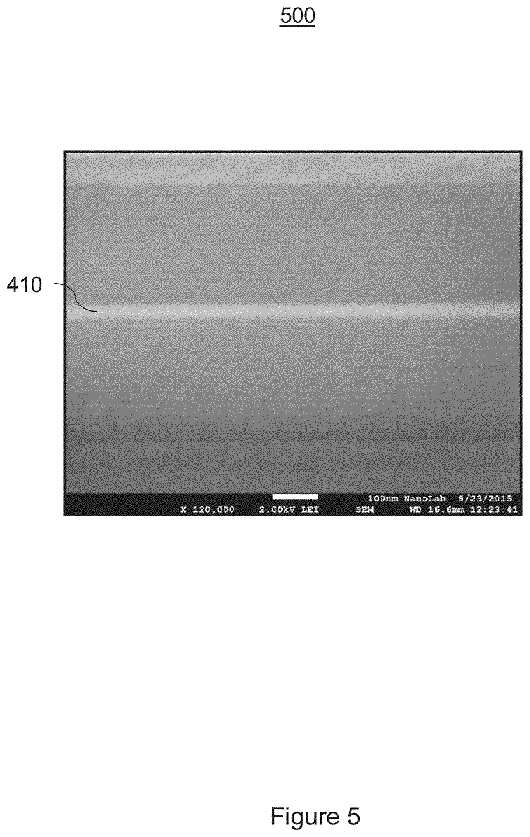

FIG. 1 is a flow diagram illustrating, in a general manner, a method 100 of fabricating a semiconductor structure with multiple quantum wells, according to examples. A corresponding example semiconductor structure is described below with reference to FIG. 5.

At block 102, a substrate is provided. The substrate comprises a binary semiconductor compound having a first lattice constant.

For example, the substrate may be an InP substrate. That is the substrate comprises mainly InP. The substrate 102 may be purely InP (within acceptable purity tolerances) or may comprise other materials such as dopants or impurities with the material comprising at least 99% InP. For example, the substrate is doped with a dopant material so that the substrate may be considered n-doped or the substrate is doped with a dopant material so that the substrate may be considered p-doped.

At block 104, the method 100 comprises depositing, at least: a first layer on the substrate, and a second layer in contact with the first layer to form a first stack of substantially planar semiconductor layers on the substrate. The first layer is of a first semiconductor alloy comprising InP and the second layer is of a second semiconductor alloy comprising InP.

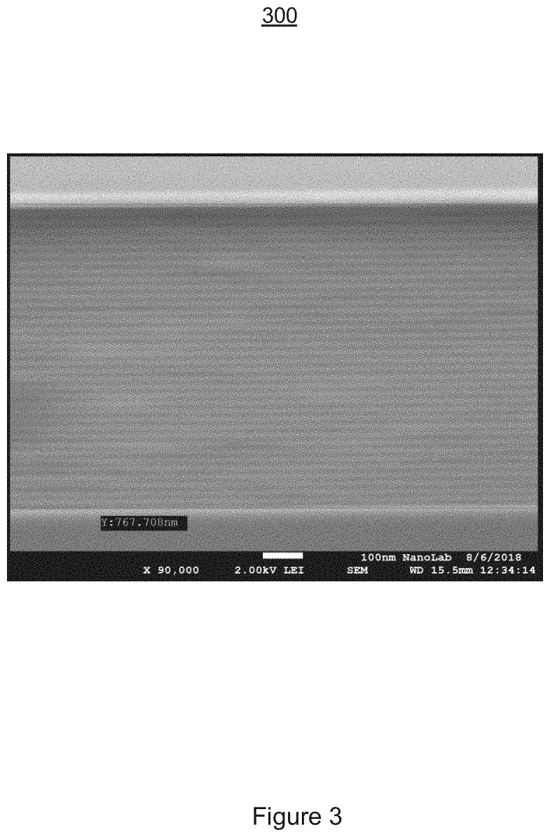

The first stack comprises a plurality of layers. A number of layers in the first stack is less than a threshold number of layers above which one or more layers of the stack would exhibit a defect. Fabrication of the first stack comprises depositing a number of layers of the first semiconductor alloy interspersed with a corresponding number of layers of the second semiconductor alloy. As described below with reference to FIG. 3, at least in some examples, particularly examples in which the first and second layers comprise InP, there is an increasing tendency for defects to occur in the semiconductor layers of the first stack with an increasing number of semiconductor layers.

By saying that the layers are substantially planar, it is envisaged that the layers are for example deposited on the substrate such that the upper surface of each of the layers is parallel with the surface of the substrate on which the first layer is deposited.

In some examples, the first layer is on the substrate in the sense that it is deposited in contact with the substrate. In other examples, the first layer is on the substrate in that it is supported by the substrate but not directly in contact with the substrate. For example, there are one or more intermediate layers such as materials not comprising InP, such as indium aluminium arsenide (InAlAs).

As a general comment in relation to the term “on” used herein, a layer specified as being in contact with a layer (such as an underlying layer) is in direct contact with that layer; whereas, a layer specified as being on a layer (such as an underlying layer) may be in direct contact with that layer or may be supported by the layer, with one or more intermediate layers (such as of a material not comprising InP) therebetween.

In some examples, each of the layers is deposited substantially across the whole surface area of the substrate (e.g. except for areas of the substrate that are clamped by a wafer clamp of a reactor in which the semiconductor is being manufactured).

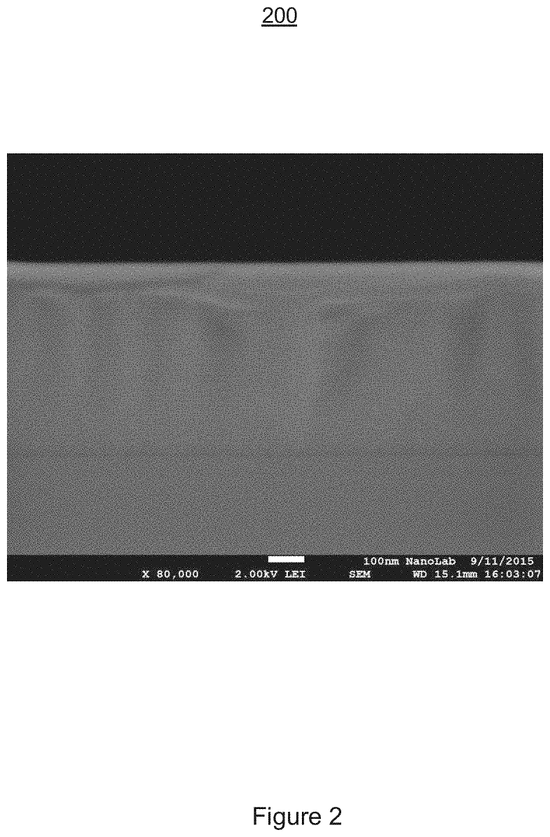

FIG. 2 is scanning electron micrograph of a semiconductor structure comprising multiple quantum wells (32 in total) comprising InP; in this example, the quantum wells are formed of thin layers of indium gallium arsenide phosphide (InGaAsP), which are arranged to be unstrained by matching of the lattice constants to that of the substrate. As can be seen in FIG. 2, growing many consecutive semiconductor quantum wells comprising InP leads to morphological defects in the layers of the semiconductor structure, which may, as described below, manifest as apparent non-planarity (e.g. undulations) in one or more layers of semiconductor. These defects can lead to failure of the epitaxial growth or to device failures in devices incorporating the semiconductor structure, which limits the number of quantum wells that can be grown in the structure.

As shown in FIG. 2, the undulations manifest in the layers of the structure as viewed in cross-section. Theses undulations may not be present at the surface of the processed structure, which may still exhibit a planar surface; this may be due, for example, to the planarizing effects of an InP layer deposited on the layers of the semiconductor structure (for example, to form an electrical contact).

The inventors have therefore appreciated that, when fabricating multiple quantum wells using InP, a problem occurs which, as far as is known, does not appear when fabricating multiple quantum well using other semiconductor material platforms. The inventors determined that, depending on the processing conditions (e.g. pressure and temperature), defects were observed when more than approximately 16 quantum wells were grown in a stack.

Accordingly, in some examples, the number of layers of each of the first and second semiconductor alloys is greater than 8 and fewer than 16, such that the total number of layers in the first stack is fewer than 32.

In contrast, FIG. 3 is a scanning electron micrograph of a semiconductor structure comprising 36 quantum wells that do not include InP; in this example, the quantum wells are formed of indium aluminium gallium arsenide (InAlGaAs). As can be seen, the quantum wells shown in FIG. 2 are substantially planar; this is despite there being many more quantum wells that can be fabricated using InP-containing quantum wells without forming defects such as those seen in FIG. 2.

To address the problem described above with reference to FIG. 2, at block 106, a third layer comprising a binary semiconductor material having the first lattice constant is deposited in contact with the first stack. For example, where the substrate is of InP, the third layer may also be of InP.

Then, at block 108, the method 100 comprises depositing, at least: a fourth layer in contact with the third layer and a fifth layer in contact with the fourth layer to form a second stack of substantially planar semiconductor layers on the third layer. The fourth layer comprises a third semiconductor alloy comprising InP and the fifth layer comprises a fourth semiconductor alloy comprising InP.

As the skilled person will appreciate, various techniques may be used to deposit the layers of semiconductor material in accordance with examples described herein. Such techniques may include chemical vapour deposition techniques such as metalorganic vapour-phase epitaxy (MOVPE) or molecular beam epitaxy (MBE).

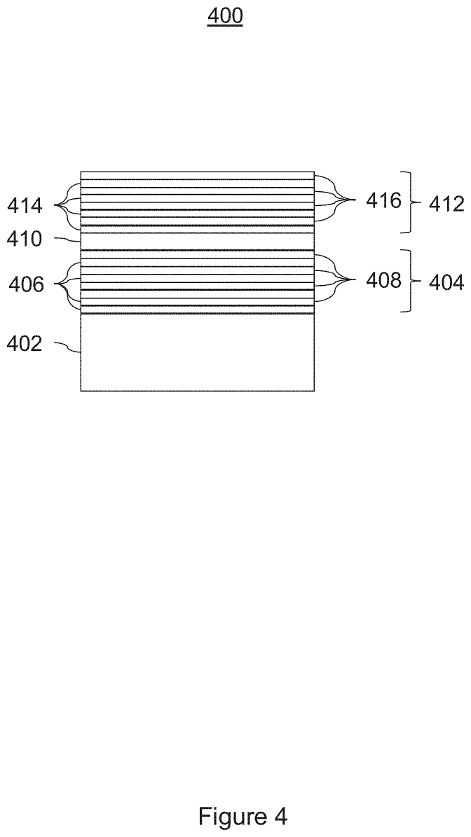

FIG. 4 is a diagram of a semiconductor structure 400, according to examples. The semiconductor structure is fabricated according to the method described above with reference to FIG. 1.

The semiconductor structure 400 comprises a substrate 402 onto which quantum wells are grown.

The semiconductor structure 400 includes a first stack 404 of quantum wells. The first stack 404 comprises multiple, alternating layers of a first semiconductor alloy 406 and a second semiconductor alloy 408. A first layer, of the first semiconductor alloy 406, is deposited on the substrate 402 and a second layer, of the second semiconductor alloy 408 is deposited in contact with the first layer of the first semiconductor alloy 406, as described above with reference to block 104 of FIG. 1. Multiple quantum wells are fabricated by alternating between the deposition process for depositing the first semiconductor alloy 406 and the deposition process for depositing the second semiconductor alloy 408.

For the reasons described above, the first stack 404 comprises fewer than 32 layers. That is the first stack comprises fewer than 16 layers of the first semiconductor alloy 406 and fewer than 16 layers of the second semiconductor alloy 408.

In some examples, each of the first and second semiconductor alloys 406, 408 comprises a ternary semiconductor alloy or a quaternary semiconductor alloy. For example, each of the first and second semiconductor alloys 406, 408 comprises InGaAsP, wherein the relative amounts of indium phosphide (InP), gallium arsenide (GaAs), indium arsenide (InAs), and gallium phosphide (GaP) differ between the first and second semiconductor alloys 406, 408. Each of the first and second semiconductor alloys 406, 408 may be doped (e.g. p-doped or n-doped).

Although it is envisaged that each of the first and second semiconductor alloys 406, 408 is unstrained (e.g. that the lattice constant of one layer is matched to the layers in which that layer is in contact) in some examples it is desirable to select lattice constants that introduce strain to, for example, modify the optical absorption or emission properties of the semiconductor structure 400.

In some examples, the layers of each of the first and second semiconductor alloys 406, 408 are less than 15 nanometers (nm).

Deposited in contact with the first stack 404 is a third layer 410. The third layer 410 is a binary semiconductor having a lattice constant substantially equal to a lattice constant of the substrate 402, as described above with reference to block 106 of FIG. 1. By substantially equal it is meant that no strain is intended to be induced by the introduction of the third layer 410.

The thickness of the third layer 410 may be in the range 4 nm to 100 nm.

Inclusion of a third semiconductor layer 410 having a lattice constant that is substantially equal to that of the substrate 402 means that the fabrication process (e.g. the method of FIG. 2) may be performed without modification of the fabrication reactor or any modification of process conditions of the reactor, such as temperature or pressure, prior to fabrication of the third layer 410. This may, in examples, provide for easy integration into existing fabrication processes.

Furthermore, adding only a single, thin layer of binary semiconductor material presents a negligible effect on the overall electro-optical properties of the semiconductor structure 400 and so performance of devices incorporating the semiconductor structure 400 is not adversely affected by the inclusion of the third layer 410.

Deposited in contact with the third layer 410, is a second stack 412 of quantum wells. The second stack 412 comprises multiple, alternating layers of a third semiconductor alloy 414 and a fourth semiconductor alloy 416. A layer of the third semiconductor alloy 414, is deposited on the third layer 410 and a layer of the fourth semiconductor alloy 416 is deposited on the layer of the third semiconductor alloy 414 deposited in contact with the third layer 410, as described above with reference to block 108. Multiple quantum wells are fabricated by alternating between the deposition process for depositing the third semiconductor alloy 414 and the deposition process for depositing the fourth semiconductor alloy 416.

For the reasons described above, the second stack 412 also comprises fewer than 32 layers. That is the first stack comprises fewer than 16 layers of the first semiconductor alloy 406 and fewer than 16 layers of the second semiconductor alloy 408.

In some examples, each of the third and fourth semiconductor alloys 414, 416 comprises a ternary semiconductor alloy or a quaternary semiconductor alloy. For example, each of the third and fourth semiconductor alloys 414, 416 comprises InGaAsP, wherein the relative amounts of indium phosphide (InP), gallium arsenide (GaAs), indium arsenide (InAs), and gallium phosphide (GaP) differ between the third and fourth semiconductor alloys (414, 416). Each of the third and fourth semiconductor alloys 414, 416 may be doped (e.g. p-doped or n-doped).

Although it is envisaged that each of the third and fourth semiconductor alloys 414, 416 is unstrained (e.g. that the lattice constants of one layer is matched to the adjacent layers) in some examples it may be desirable to select lattice constants that introduce strain to, for example, modify the optical absorption or emission properties of the semiconductor structure 400.

In some examples, the processes described with reference to blocks 106 and 108 of FIG. 1 may be repeated to further increase the number of quantum wells in the semiconductor structure 400.

Although in the example shown in FIG. 4, the first stack 404 and the second stack 412 have equal numbers of layer so that the third layer 410 is in the centre of the overall stack, in other examples, the first stack 404 has a different number of quantum well layers to the second stack 412. That is the third layer 410 may be elsewhere within the semiconductor structure 400, not necessarily in the exact middle of the layers of quantum wells. For example, in a semiconductor structure 400 comprising 25 quantum wells layers, the third layer 410 may be deposited after 9 quantum wells have been fabricated and 16 quantum wells may be fabricated above the third layer 410.

FIG. 5 is a scanning is a scanning electron micrograph of a semiconductor structure comprising 24 quantum wells comprising InP; in this example, the quantum wells are formed of thin layers of indium gallium arsenide phosphide (InGaAsP), which are arranged to be unstrained by matching of the lattice constants to that of the substrate. The third layer 410 described above is identifiable as a bright band approximately in the centre of a stack of darker bands (which correspond to quantum well structures). As can be seen in FIG. 2, introduction of the third layer 410, which is a single thin layer of a material enables a significant increase in the number of InP-containing quantum well layers that can be fabricated in a semiconductor structure before defects such as those shown in FIG. 2 become present. Accordingly, the method described above with reference to FIG. 1 provides a simple and efficient way to allow the growth of thicker stacks of quantum wells containing InP.

Increasing the total thickness of a stack of repeating epitaxial quantum well layers can be useful by, for example, increasing optical confinement in the semiconductor. For example, a more efficient electro-absorption or electro-refractive modulator can be produced, because the efficiency of electro-absorption and electro-refractive modulators is related to optical confinement.

The above examples are to be understood as illustrative examples. It is to be understood that any feature described in relation to any one example may be used alone, or in combination with other features described, and may also be used in combination with one or more features of any other of the examples, or any combination of any other of the examples. Furthermore, equivalents and modifications not described above may also be employed without departing from the scope of the accompanying claims.

What is claimed is:

1. A method of fabricating a semiconductor structure with multiple quantum wells, the method comprising:
providing a substrate comprising a binary semiconductor compound having a first lattice constant;
depositing at least:
a first layer on the substrate, the first layer of a first semiconductor alloy comprising InP, and
a second layer in contact with the first layer, the second layer of a second semiconductor alloy comprising InP, to form a first stack of substantially planar semiconductor layers on the substrate;
depositing in contact with the first stack a third layer of a binary semiconductor compound having the first lattice constant;
depositing at least:
a fourth layer on the third layer, the fourth layer comprising a third semiconductor alloy comprising InP, and
a fifth layer in contact with the fourth layer, the fifth layer comprising a fourth semiconductor alloy comprising InP,
to form a second stack of substantially planar semiconductor layers on the third layer.

2. The method of claim 1, wherein the first stack comprises a plurality of layers, the plurality of layers comprising the first layer and the second layer, wherein a total number of layers in the first stack is less than a threshold number of layers above which one or more layers of the first stack would exhibit a defect.

3. The method of claim 2, wherein the defect comprises at least one of: one or more undulation or an irregularity in planarity.

4. The method of claim 1, wherein the first stack comprises a plurality of layers, the plurality of layers comprising the first layer and the second layer, and without the third layer and with the first stack comprising additional layers, there would be a tendency at least for one layer of the first stack to exhibit a defect.

5. The method of claim 4, wherein the defect comprises at least one of: one or more undulation or an irregularity in planarity.

6. The method of claim 1, wherein the third layer at least partly cancels a tendency for a substantially planar semiconductor layer of the second stack to exhibit a defect, such that the second stack is substantially free from the defect.

7. The method of claim 6, wherein the defect comprises at least one of: one or more undulation or an irregularity in planarity.

8. The method of claim 1, wherein the first stack comprises fewer than 32 layers.

9. The method of claim 1, wherein at least one of:
the third semiconductor alloy is substantially the same as the first semiconductor alloy,
the fourth semiconductor alloy is substantially the same as the second semiconductor alloy, or
the first, second, third and fourth semiconductor alloy, respectively, is one of a ternary semiconductor alloy or a quaternary semiconductor alloy.

10. The method of claim 1, wherein each of the first, second, third and fourth semiconductor alloys is of InGaAsP, wherein relative amounts of InP, GaAs, InAs, and GaP differ between the first and second semiconductor alloys and between the third and fourth semiconductor alloys.

11. The method of claim 1, wherein a total number of layers in the second stack is equal to a total number of layers in the first stack.

12. The method of claim 1, wherein at least one of the third layer or the substrate is of InP.

13. The method of claim 1, wherein a thickness of the third layer is at least one of greater than 4 nanometres or less than 100 nanometres.

14. The method of claim 1, wherein the first layer is in contact with the substrate.

15. A semiconductor structure with multiple quantum wells, the semiconductor structure comprising:
a substrate comprising a binary semiconductor compound having a first lattice constant;
a first stack of substantially planar semiconductor layers on the substrate, the first stack comprising at least:
a first layer on the substrate, the first layer of a first semiconductor alloy comprising InP, and
a second layer in contact with the first layer, the second layer of a second semiconductor alloy comprising InP;
a third layer in contact with the first stack, the third layer of a binary semiconductor compound having the first lattice constant; and
a second stack of substantially planar semiconductor layers on the third layer, the second stack comprising at least:
a fourth layer on the third layer, the fourth layer comprising a third semiconductor alloy comprising InP, and
a fifth layer in contact with the fourth layer, the fifth layer comprising a fourth semiconductor alloy comprising InP.

16. The semiconductor structure of claim 15, wherein at least one of:
the first stack comprises a plurality of layers, the plurality of layers comprising the first layer and the second layer, wherein a total number of layers in the first stack is less than a threshold number of layers above which one or more layers of the first stack would exhibit a defect;
the first stack comprises a plurality of layers, the plurality of layers comprising the first layer and the second layer, and without the third layer and with the first stack comprising additional layers, there would be a tendency at least for one layer of the first stack to exhibit a defect; or
the third layer at least partly cancels a tendency for a substantially planar semiconductor layer of the second stack to exhibit a defect, such that the second stack is substantially free from the defect.

17. The semiconductor structure of claim 16, wherein the defect comprises at least one of: one or more undulation or irregularity in planarity.

18. The semiconductor structure of claim 15, wherein at least one of the substrate or the third layer is of InP.

19. The semiconductor structure of claim 15, wherein a thickness of the third layer is at least one of greater than 4 nanometres or less than 100 nanometres.

20. A device comprising a semiconductor structure with multiple quantum wells, the semiconductor structure comprising:
a substrate comprising a binary semiconductor compound having a first lattice constant;
a first stack of substantially planar semiconductor layers on the substrate, the first stack comprising at least:
a first layer on the substrate, the first layer of a first semiconductor alloy comprising InP, and
a second layer in contact with the first layer, the second layer of a second semiconductor alloy comprising InP;
a third layer in contact with the first stack, the third layer of a binary semiconductor compound having the first lattice constant; and
a second stack of substantially planar semiconductor layers on the third layer, the second stack comprising at least:
a fourth layer on the third layer, the fourth layer comprising a third semiconductor alloy comprising InP, and
a fifth layer in contact with the fourth layer, the fifth layer comprising a fourth semiconductor alloy comprising InP,
wherein the device is at least one of an electro-absorption modulator or an electro-refractive device.
